(19) United States
(12) Patent Application Publication
(10) Pub. No.: US 2020/0013658 A1
(43) Pub. Date: Jan. 9, 2020

(54) ELECTROSTATIC CHUCK UNIT AND THIN FILM DEPOSITION APPARATUS INCLUDING THE SAME

(71) Applicant: Samsung Display Co., Ltd., Yongin-si (KR)

(72) Inventors: Junhyeuk KO, Yongin-si (KR); Euigyu KIM, Yongin-si (KR); Minchul SONG, Yongin-si (KR); Byungik KONG, Yongin-si (KR); Jaesuk MOON, Yongin-si (KR); Soohyun MIN, Yongin-si (KR); Seungjin LEE, Yongin-si (KR); Seungju HONG, Yongin-si (KR)

(21) Appl. No.: 16/363,430

(22) Filed: Mar. 25, 2019

(30) Foreign Application Priority Data
Jul. 4, 2018 (KR) 10-2018-0077892

(51) Int. Cl. H01L 21/683; H01L 51/56; C23C 14/04; C23C 14/50

(52) U.S. Cl. CPC H01L 21/6833; H01L 51/56; H01L 27/3244; C23C 14/50; C23C 14/042

(57) ABSTRACT

An electrostatic chuck unit includes a first wiring portion configured to generate a relatively weak electrostatic force and a second wiring portion configured to generate a relatively strong electrostatic force.

### CROSS-REFERENCE TO RELATED APPLICATION

This application claims priority to, and the benefit of, Korean Patent Application No. 10-2018-0077892, filed on Jul. 4, 2018, in the Korean Intellectual Property Office, the disclosure of which is incorporated herein in its entirety by reference.

### BACKGROUND

### 1. Field

One or more embodiments relate to thin film deposition apparatuses for generating vapor of a deposition source and for forming a thin film on a substrate through a mask, and also to a thin film deposition apparatus including an improved electrostatic chuck unit for bringing a mask and a substrate into close contact with each other and for supporting the mask and the substrate.

### 2. Description of the Related Art

In general, an organic light-emitting display device generates an image by emitting light according to a recombination of holes and electrons, which are injected respectively into an anode and a cathode, in an emission layer. The organic light-emitting display device has a stacked structure in which the emission layer is interposed between the anode and the cathode. However, because it is difficult to obtain high-efficiency light emission with the above-described structure, an electron injection layer, an electron transport layer, a hole transport layer, and a hole injection layer are selectively added to the emission layer as an intermediate layer between two electrodes, that is, between the anode and the cathode.

The electrodes and the intermediate layer of the organic light-emitting display device may be formed by various methods. One of the various methods is a deposition method. When the organic light-emitting display device is manufactured by using the deposition method, a mask having pattern holes that correspond to a thin film pattern to be formed is aligned on a substrate, and a raw material of a thin film is deposited on the substrate through the pattern holes of the mask to thereby form a thin film of a desired pattern.

In this case, an electrostatic chuck unit is used to bring the mask and the substrate into close contact with each other, and to firmly support the mask and the substrate. That is, the electrostatic chuck unit is located opposite the mask with the substrate therebetween, and pulls the substrate and the mask with an electrostatic force, so that the mask and the substrate firmly adhere to each other while the deposition is performed.

### SUMMARY

Due to a level difference in a periphery of the mask, a repulsive force, not an attraction force, occurs at an end portion of a cell, which is a region where the pattern holes are formed in the mask. Thus, adhesion between a substrate and the mask is relatively lowered. In this case, a gap is formed between the substrate and the mask, and deposition might not be accurately performed at a desired position. Thus, there is a high possibility that products manufactured in this manner may be defective.

One or more embodiments include an electrostatic chuck unit that improves adhesion at an end portion of a cell, and include a thin film deposition apparatus including the electrostatic chuck unit.

Additional aspects will be set forth in part in the description that follows and, in part, will be apparent from the description, or may be learned by practice of the presented embodiments.

According to one or more embodiments, an electrostatic chuck unit includes electrostatic chuck body including first and second wiring portions each including a plurality of wiring line configured to generate an electrostatic force to generate attraction between a substrate and a mask via the electrostatic force, wherein the first wiring portion is configured to generate a weaker electrostatic force than the second wiring portion.

An interval between wiring lines in the second wiring portion may be less than an interval between wiring lines in the first wiring portion.

A width of each of wiring lines in the second wiring portion may be greater than a width of each of wiring lines in the first wiring portion.

A thickness of each of wiring lines in the second wiring portion may be greater than that of each of wiring lines in the first wiring portion.

The electrostatic chuck unit may further include a plurality of pressing protrusions on a surface of the electrostatic chuck body that face the substrate and the mask.

The plurality of pressing protrusions may be at a position corresponding to the second wiring portion.

The plurality of pressing protrusions may be at a position corresponding to the first wiring portion and at a position corresponding to the second wiring portion, and ones of the pressing protrusions at the position may correspond to the second wiring portion are more densely distributed than ones of the pressing protrusions at the position corresponding to the first wiring portion.

The electrostatic chuck body may further include a cooler.

The electrostatic chuck unit may further include a magnet for generating a magnetic force for attracting the mask.

The mask may include a cell in which a plurality of pattern holes are distributed and in which a step difference portion is formed in an end portion of the cell, wherein the second wiring portion is positioned to correspond to the step difference portion.

According to one or more embodiments, a thin film deposition apparatus includes a chamber, a deposition source supplier configured to supply a deposition source to a substrate as a deposition target in the chamber, a mask having a cell with a plurality of pattern holes formed therein for patterning deposition to the substrate, and an electrostatic chuck unit configured to support the mask and the substrate to generate attraction between the mask and the substrate, and including an electrostatic chuck body configured to generate an electrostatic force for generating the attraction between the substrate and the mask via the electrostatic force, and first and second wiring portions each including a plurality of wiring lines in the electrostatic chuck body to generate the electrostatic force, wherein the first wiring portion is configured to generate a weaker electrostatic force than the second wiring portion.

An interval between wiring lines in the second wiring portion may be less than an interval between wiring lines in the first wiring portion.

A width of each of wiring lines in the second wiring portion may be greater than a width of each of wiring lines in the first wiring portion.

A thickness of each of wiring lines in the second wiring portion may be greater than a thickness of each of wiring lines in the first wiring portion.

The thin film deposition apparatus may further include a plurality of pressing protrusions on a surface of the electrostatic chuck body facing the substrate and the mask.

The plurality of pressing protrusions may be at a position corresponding to the second wiring portion.

The plurality of pressing protrusions may be at a position corresponding to the first wiring portion and at a position corresponding to the second wiring portion, wherein ones of the pressing protrusions at the position corresponding to the second wiring portion are more densely distributed than ones of the pressing protrusions at the position corresponding to the first wiring portion.

The electrostatic chuck body may include a cooler.

The thin film deposition apparatus may further include a magnet for attracting the mask with a magnetic force.

A step difference portion may be formed in an end portion of the cell, wherein the second wiring portion is positioned to correspond to the step difference portion in the mask.

Aspects and features other than those in the aforementioned descriptions may be understood more readily by reference to the following accompanying drawings, claims, and detailed descriptions of embodiments.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a thin film deposition apparatus including an electrostatic chuck unit according to an embodiment;

FIG. 2 is a perspective view of a mask frame assembly shown in FIG. 1;

FIG. 3 is a cross-sectional view taken along a line of FIG. 2;

FIG. 4 is a plan view of the electrostatic chuck unit shown in FIG. 1;

FIG. 5 is a plan view of an electrostatic chuck unit according to another embodiment;

FIGS. 6 to 10 are cross-sectional views of an electrostatic chuck unit according to another embodiment; and

FIG. 11 is a cross-sectional view of a structure of an organic light-emitting display device as an example of a substrate shown in FIG. 1.

### DETAILED DESCRIPTION

As the disclosure allows for various changes and numerous embodiments, particular embodiments will be illustrated in the drawings and described in detail in the written description. Effects and features of the disclosure and methods of accomplishing the same may be understood more readily by reference to the following detailed description of preferred embodiments and the accompanying drawings. The disclosure may, however, be embodied in many different forms and should not be construed as being limited to the embodiments set forth herein.

Reference will now be made in detail to embodiments, examples of which are illustrated in the accompanying drawings, wherein components that are the same or are in correspondence are rendered the same reference numeral regardless of the figure number, and redundant explanations are omitted.

Throughout the specification, terms as “first,” “second,” etc., may not be used for purposes of limitation but may be used to distinguish one component from another.

Throughout the specification, a singular form may include plural forms, unless there is a particular description contrary thereto.

Throughout the specification, it will be further understood that the terms “comprise”, “include,” and/or “have,” when used in this specification, specify the presence of stated features, and/or components, but do not preclude the presence or addition of one or more other features, and/or components.

In the drawings, the thicknesses of layers and regions are exaggerated for clarity. For example, the thicknesses and sizes of elements in the drawings are arbitrarily shown for convenience of description, thus, the spirit and scope of the present disclosure are not necessarily defined by the drawings.

Also, it should also be noted that in some alternative implementations, the steps of all methods described herein may occur out of the order. For example, two steps illustrated in succession may in fact be executed substantially concurrently or the two steps may sometimes be executed in the reverse order.

Throughout the specification, it will also be understood that when a layer, a region, an element, or the like is referred to as being “connected to” or “coupled with” another layer, region, or element, it can be directly connected to or coupled with the other layer, region, or element, or it can be indirectly connected to or coupled with the other layer, region, or element by having an intervening layer, region, or element interposed therebetween. For example, throughout the specification, when a layer, a region, an element, or the like is referred to as being “electrically connected to” or “electrically coupled with” another layer, region, or element, it can be electrically connected to or coupled with the other layer, region, or element in a direct manner, or it can be electrically connected to or coupled with the other layer, region, or element in an indirect manner by having an intervening layer, region, or element interposed therebetween.

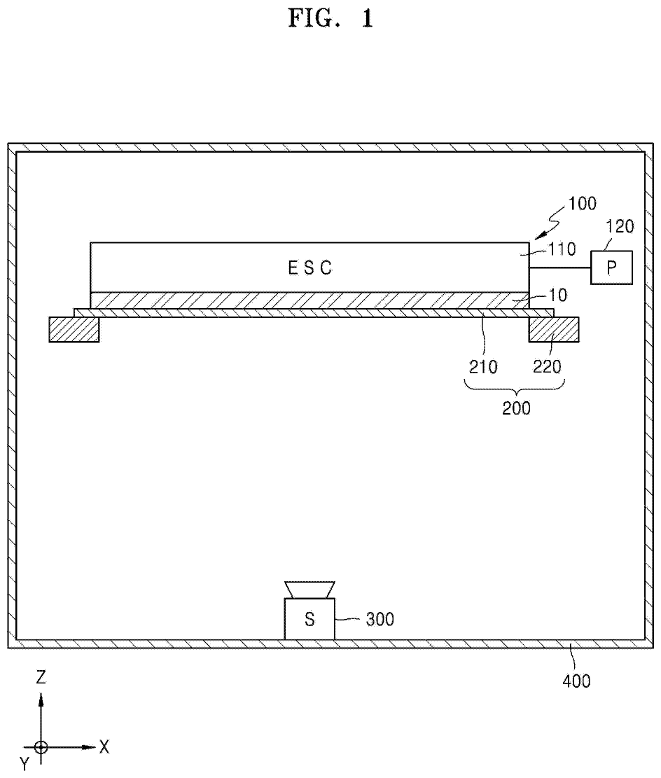

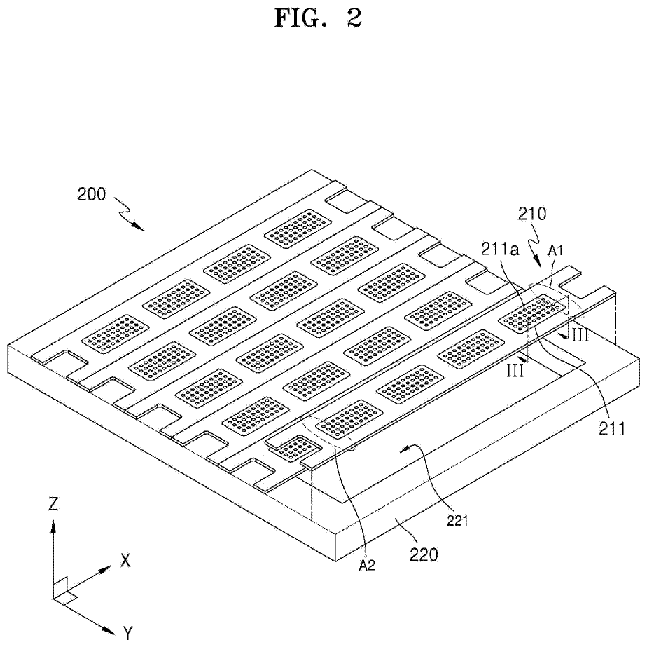

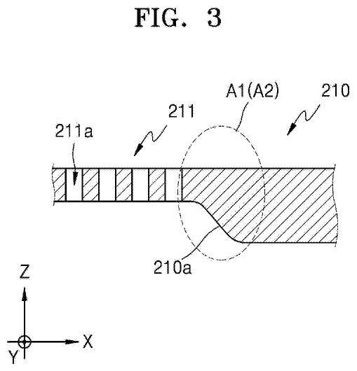

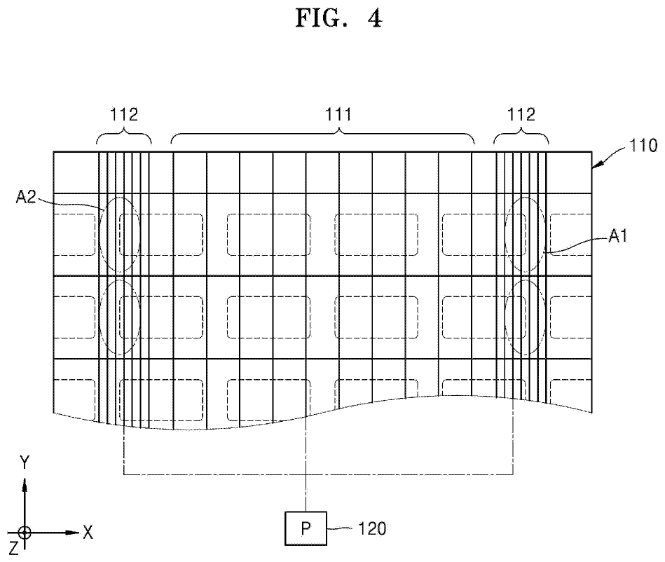

FIG. 1 is a cross-sectional view of a thin film deposition apparatus including an electrostatic chuck unit 100, according to an embodiment. FIG. 2 is a perspective view of a mask frame assembly shown in FIG. 1. FIG. 3 is a cross-sectional view taken along a line of FIG. 2. FIG. 4 is a plan view of the electrostatic chuck unit shown in FIG. 1.

As shown in FIG. 1, the thin film deposition apparatus according to the present embodiment includes a deposition source unit/deposition source supplier 300 for spraying a deposition source in a chamber 400, a mask 210 that is in close contact with a surface of a substrate 10 that is a deposition target, and an electrostatic chuck unit 100 that is positioned on a surface opposite the surface and attracts the substrate 10 and the mask 210 via an electrostatic force to bring the substrate 10 and the mask 210 into close contact with each other.

Accordingly, when the deposition source supplier 300 sprays a deposition source in the chamber 400, the deposition source is deposited on the substrate 10 through pattern holes 211a (see FIG. 2) formed in the mask 210, and thus, a thin film of a pattern is formed.

In this case, electricity is supplied from a power source 120 of the electrostatic chuck, unit 100 to first and second wiring portions 111 and 112 (see first and second wiring portions 111 and 112a in FIG. 4) of an electrostatic chuck body 110 to generate an electrostatic force, and the mask 210 and the substrate 10 are firmly brought into close contact with each other by the electrostatic force.

The mask 210 is used in the form of a mask frame assembly 200 in which an edge portion of the mask 210 is supported by a frame 220, and has a structure as shown in FIG. 2.

As shown in FIG. 2, the frame 220 having an opening 221 at its center is provided, and a plurality of stick-shaped masks (e.g., relatively long and thin masks) 210 are supported on the frame 220 (e.g., by ends thereof). Each of the masks 210 has both ends fixed to the frame 220, and a plurality of cells 211 between both ends of each of the masks 210 are arranged in (e.g., aligned with, or corresponding to) the opening 221. Each of the cells 211 is a region where a plurality of pattern holes 211a are formed, and a thin film is formed on the substrate 10 when the deposition source passes through the plurality of pattern holes 211a of the cell 211. In general, the mask 210 includes a metal material.

A step difference portion, of which a thickness varies relatively abruptly, is formed in end portions A1 and A2 of the cells 211 near respective ends of each mask 210. That is, as shown in FIG. 3, a step difference portion 210a, of which a thickness varies abruptly (e.g., at which a thickness of the mask 210 abruptly increases), is formed in the end portions A1 and A2. In a region where the step difference portion 210a is formed, a repulsive force occurs when an electrostatic force occurs, and thus, adhesion between the mask 210 and the substrate 10 is lower than in other regions.

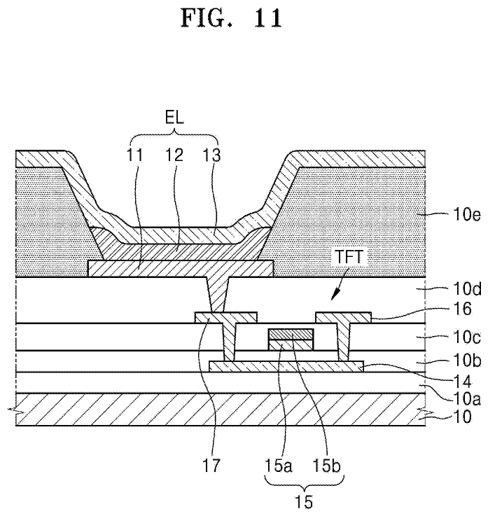

Accordingly, in the present embodiment, the first and second wiring portions 111 and 112 (e.g., see FIG. 4) in the electrostatic chuck body 110 are arranged in a differential manner to suppress the above-described problem of the repulsive force. The detailed structure thereof will be described later. First, the structure of the organic light-emitting display device will be briefly described with reference to FIG. 11 as an example of the substrate 10 on which the deposition is performed by the thin film deposition apparatus according to the present embodiment.

FIG. 11 is a cross-sectional view of a structure of an organic light-emitting display device as an example of a substrate shown in FIG. 1.

As shown in FIG. 11, the organic light-emitting display device includes a thin film transistor TFT and an organic light-emitting device EL.

An active layer 14 is formed on a buffer layer 10a on the substrate 10. The active layer 14 includes a source and a drain that are heavily doped with N-type or P-type impurities. The active layer 14 may include an oxide semiconductor. For example, the oxide semiconductor may include an oxide of a material selected from Group 12, 13, and 14 metal elements, such as zinc (Zn), indium (In), gallium (Ga), tin (Sn), cadmium (Cd), and germanium (Ge), and a combination thereof. For example, the active layer 14 including an oxide semiconductor may include G-I-Z-O[(In₂O₃)ₐ(Ga₂O₃)_{b}(ZnO)_{c}] (where a, b, and c are real numbers satisfying conditions of a≥0, b≥0, and c>0, respectively.). A gate electrode 15 is formed on the active layer 14 with a gate insulating layer 10b therebetween. The gate electrode 15 includes two layers, that is, the gate electrode 15 includes a gate lower layer 15a and a gate upper layer 15b.

A source electrode 16 and a drain electrode 17 are formed on the gate electrode 15. An interlayer insulating layer 10c is provided between the gate electrode 15 and the source and drain electrodes 16 and 17, and a passivation layer 10d is positioned between a pixel electrode 11 of the organic light-emitting device EL and the source and drain electrodes 16 and 17.

A pixel-defining layer 10e is formed over the pixel electrode 11. An opening is formed in the pixel-defining layer 10e to expose the pixel electrode 11, and then an emission layer 12 is formed thereon through deposition.

The organic light-emitting device EL emits red, green, and blue light according to a current flow to thereby display image information. The organic light-emitting device EL includes the pixel electrode 11 connected to the drain electrode 17 of the thin film transistor TFT, an opposite electrode 13 facing the pixel electrode 11, and the emission layer 12 positioned between the pixel electrode 11 and the opposite electrode 13 to emit light.

For example, a hole injection layer (HIL), a hole transport layer (HTL), an electron transport layer (ETL), and an electron injection layer (EIL) may be stacked adjacent to the emission layer 12.

Various thin films on the substrate 10 may be formed through deposition by the thin film deposition apparatus.

In this case, when a portion exists where adhesion to the substrate 10 is lowered due to a step difference of the mask 210, a deposition failure may occur. Therefore, to compensate for the lowered adhesion in this portion, the electrostatic chuck unit 100 according the present embodiment has a differential arrangement structure of the first and second wiring portions 111 and 112, as shown in FIG. 4.

That is, the first wiring portion 111 having a relatively large interval between wiring, lines is formed at a position corresponding to a central portion of the mask 210 in which there is no step difference portion, and the second wiring portion(s) 112 having a relatively small interval between wiring lines is formed at a position(s) corresponding to the end portions A1 and A2 of the respective cells 211 in which there is the respective step difference portions 210a. The relatively small wiring interval in the second wiring portion 112 means that more wiring lines are arranged in a unit area when compared to the first wiring portion 111. Thus, a larger electrostatic force may be generated in the second wiring portion 112 having the relatively small wiring interval than in the first wiring portion 111 having the relatively large wiring interval.

In summary, the second wiring portion 112 having the small wiring interval is provided at a position corresponding to the end portions A1 and A2 of the cell 211, which may otherwise have a relatively low adhesion due to the step difference portion 210a, and the first wiring portion 111 having the large wiring interval is provided at positions other than the positions corresponding to the end portions A1 and A2, and thus, a difference in adhesion due to the structure of the mask 210 is compensated for by a differential action of the electrostatic force.

In this case, the deposition failure due to the weakening of the adhesion may be effectively prevented, thereby improving the performance and reliability of products. The second wiring portion 112 is formed over a wider area than the areas of the end portions A1 and A2 where the step difference portions 210a are formed to increase a use range of the products. Thus, the deposition failure may be effectively prevented even in a case when a size of the cell 211 is changed and the positions of the end portions A1 and A2 are slightly changed. In addition to this structure, the amount of electricity supplied from the power source 120 to the first wiring portion 111 and the second wiring portion 112 may also be controlled differently such that a difference in the electrostatic force may be adjusted more precisely.

Therefore, when thin film deposition is performed using the electrostatic chuck unit 100 having the above-described structure, stable deposition may be performed in a state where the substrate 10 and the mask 210 are firmly in close contact with each other, that is, in a state where the substrate 10 and the mask 210 firmly adhere to each other.

Modifications in which components may be modified or additionally implemented within the spirit and scope of the above-described embodiments are described.

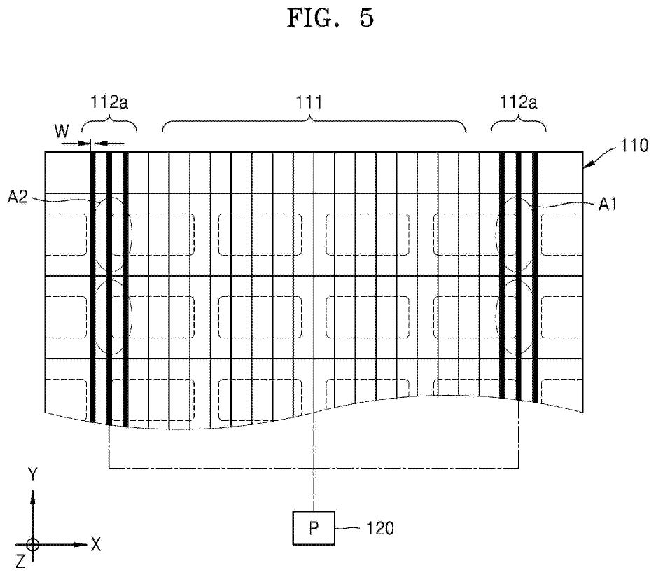

FIG. 5 is a plan view of an electrostatic chuck unit according to another embodiment.

Referring to FIG. 5, a first wiring portion 111 for generating a relatively weak electrostatic force and a second wiring portion 112a for generating a relatively strong electrostatic force are provided in an electrostatic chuck body 110, as in the electrostatic chuck unit of FIG. 4. In the electrostatic chuck unit of FIG. 4, an interval between wiring lines of the second wiring portion 112a is decreased when compared to the wiring lines of the first wiring portion 111 to increase an electrostatic force. Contrastingly, in the electrostatic chuck unit of FIG. 5, a width W of each of the wiring lines in a second wiring portion 112a is larger than that of each of the wiring lines in a first wiring portion 111 to increase an electrostatic force.

Accordingly, in the electrostatic chuck unit of FIG. 5, the second wiring portion 112a having wide wiring lines is provided at a position corresponding to the end portions A1 and A2 of the cell 211 (see FIG. 2), which may otherwise have a relatively low adhesion due to a step difference portion 210a, to thereby compensate for a difference in adhesion due to the structure of the mask 210 (see FIG. 2) by a differential action of the electrostatic force.

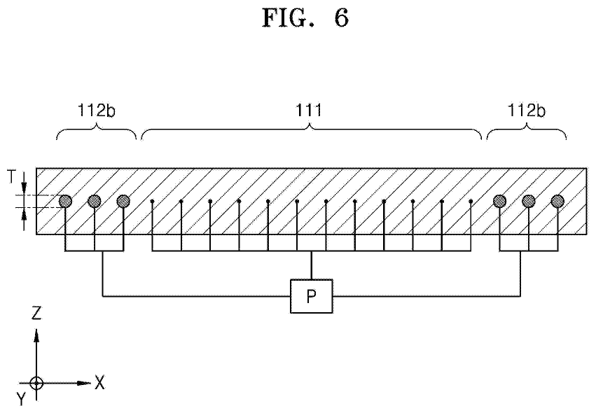

FIGS. 6 to 10 are cross-sectional views of an electrostatic chuck unit according to another embodiment.

FIG. 6 illustrates an example in which a thickness T of each of the wiring lines in a second wiring portion 112b is larger than that of each of the wiring lines in a first wiring portion 111 to increase an electrostatic force.

Accordingly, the second wiring portion 112b having thick wiring lines is provided at a position corresponding to the end portions A1 and A2 of the cell 211 (see FIG. 2) to thereby compensate for a difference in adhesion due to the structure of the mask 210 (see FIG. 2) by a differential action of the electrostatic force.

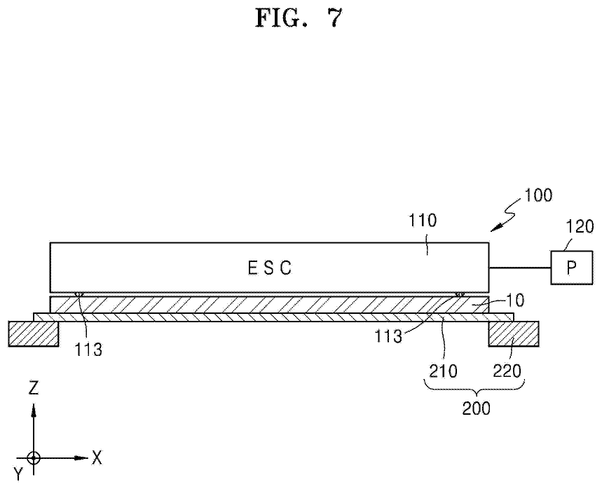

FIG. 7 illustrates an example in which pressing protrusions 113 are further formed on a surface of an electrostatic chuck body 110 that faces a substrate 10, in addition to the differential wiring structures described with reference to FIGS. 4 to 6. The pressing protrusions 113 increase an adhesive force by applying a physical pressure to the substrate 10. The present embodiment illustrates a structure in which the pressing protrusions 113 are only in the end portions A1 and A2 where there are the second wiring portions 112, 112a, and 112b.

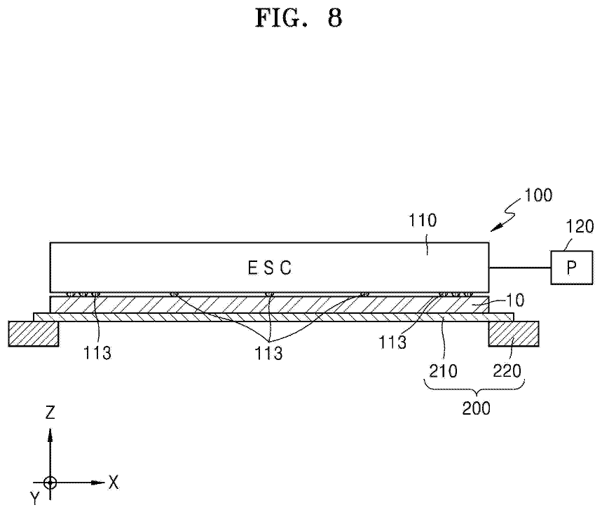

FIG. 8 illustrates a structure in which pressing protrusions 113 as illustrated in FIG. 7 are formed on the entire surface of an electrostatic chuck body 110. The pressing protrusions 113 are roughly arranged (e.g., are relatively spaced apart) in a central portion where there is the first wiring portion 111, and are more closely arranged in the end portions A1 and A2 where there are the second wiring portions 112, and thus, the lowering of adhesion is also compensated for by the differential arrangement of the pressing protrusions 113.

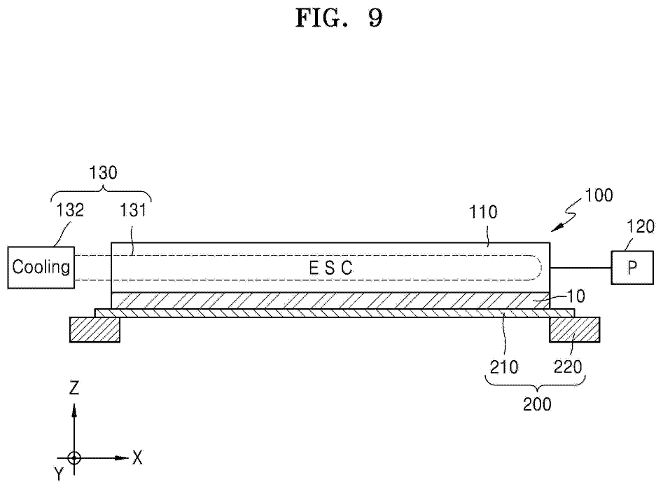

FIG. 9 illustrates an example in which an electrostatic chuck body 110 is provided with a cooler 130 while having the above-described electrostatic force differential structure. Because a chamber 400 in which deposition is performed is at a high-temperature atmosphere, if a refrigerant pipe 131 and a refrigerant pump 132 are installed to circulate a refrigerant, the risk of deformation due to high temperature may be prevented.

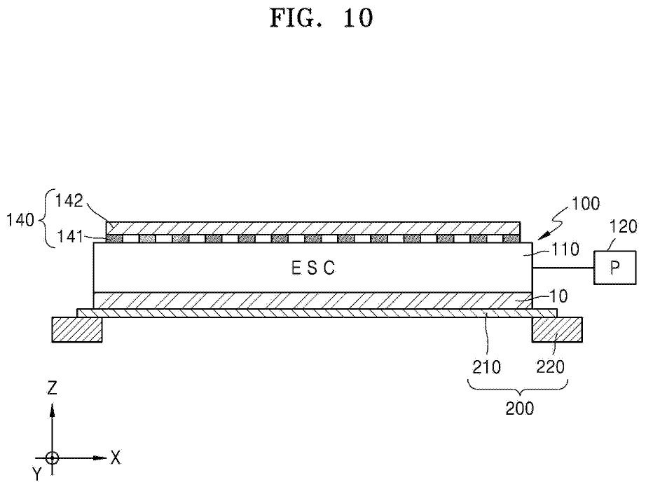

FIG. 10 illustrates a structure having the above-described electrostatic force differential structure, and further including a magnet unit 140. That is, the magnet unit 140 including a yoke plate 142 and a magnet 141 is added onto a first wiring portion 111 of an electrostatic chuck body 110 to bring a substrate 10 and a mask 210 into close contact with each other not only by an electrostatic force, but also by a magnetic force. Particularly, when the substrate 10 is large, the centers of the substrate 10 and the mask 210 may be sagged due to the weight thereof when deposition is performed after the substrate 10 and the mask 210 are mounted, and in this case, the mask 210 including a metal material is attracted by a magnetic force of the magnet 141 to thereby prevent sagging.

Therefore, such various modifications are possible.

As described above, according to the electrostatic chuck unit and the thin film deposition apparatus according to the described embodiments, an electrostatic force may be reinforced in an end portion(s) of a cell otherwise having poor adhesion between a substrate and a mask, and thus, a deposition failure due to the weakening of adhesion may be effectively prevented, and as a result, the performance and reliability of products may be improved (e.g., a deposition source may be more consistently deposited across the substrate).

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims, with functional equivalents thereof to be included.

What is claimed is:

1. An electrostatic chuck unit comprising:
an electrostatic chuck body comprising first and second wiring portions each including a plurality of wiring line configured to generate an electrostatic force to generate attraction between a substrate and a mask via the electrostatic force,
wherein the first wiring portion is configured to generate a weaker electrostatic force than the second wiring portion.

2. The electrostatic chuck unit of claim 1, wherein an interval between wiring lines in the second wiring portion is less than an interval between wiring lines in the first wiring portion.

3. The electrostatic chuck unit of claim 1, wherein a width of each of wiring lines in the second wiring portion is greater than a width of each of wiring lines in the first wiring portion.

4. The electrostatic chuck unit of claim 1, wherein a thickness of each of wiring lines in the second wiring portion is greater than that of each of wiring lines in the first wiring portion.

5. The electrostatic chuck unit of claim 1, further comprising a plurality of pressing protrusions on a surface of the electrostatic chuck body that face the substrate and the mask.

6. The electrostatic chuck unit of claim 5, wherein the plurality of pressing protrusions are at a position corresponding to the second wiring portion.

7. The electrostatic chuck unit of claim 5, wherein the plurality of pressing protrusions are at a position corresponding to the first wiring portion and at a position corresponding to the second wiring portion, and
wherein ones of the pressing protrusions at the position corresponding to the second wiring portion are more densely distributed than ones of the pressing protrusions at the position corresponding to the first wiring portion.

8. The electrostatic chuck unit of claim 1, wherein the electrostatic chuck body further comprises a cooler.

9. The electrostatic chuck unit of claim 1, further comprising a magnet for generating a magnetic force for attracting the mask.

10. The electrostatic chuck unit of claim 1, wherein the mask comprises a cell in which a plurality of pattern holes are distributed and in which a step difference portion is formed in an end portion of the cell,
wherein the second wiring portion is positioned to correspond to the step difference portion.

11. A thin film deposition apparatus comprising:
a chamber;
a deposition source supplier configured to supply a deposition source to a substrate as a deposition target in the chamber;
a mask having a cell with a plurality of pattern holes formed therein for patterning deposition to the substrate; and
an electrostatic chuck unit configured to support the mask and the substrate to generate attraction between the mask and the substrate, and comprising
an electrostatic chuck body configured to generate an electrostatic force for generating the attraction between the substrate and the mask via the electrostatic force, and
first and second wiring portions each including a plurality of wiring lines in the electrostatic chuck body to generate the electrostatic force,
wherein the first wiring portion is configured to generate a weaker electrostatic force than the second wiring portion.

12. The thin film deposition apparatus of claim 11, wherein an interval between wiring lines in the second wiring portion is less than an interval between wiring lines in the first wiring portion.

13. The thin film deposition apparatus of claim 11, wherein a width of each of wiring lines in the second wiring portion is greater than a width of each of wiring lines in the first wiring portion.

14. The thin film deposition apparatus of claim 11, wherein a thickness of each of wiring lines in the second wiring portion is greater than a thickness of each of wiring lines in the first wiring portion.

15. The thin film deposition apparatus of claim 11, further comprising a plurality of pressing protrusions on a surface of the electrostatic chuck body facing the substrate and the mask.

16. The thin film deposition apparatus of claim 15, wherein the plurality of pressing protrusions are at a position corresponding to the second wiring portion.

17. The thin film deposition apparatus of claim 15, wherein the plurality of pressing protrusions are at a position corresponding to the first wiring portion and at a position corresponding to the second wiring portion, and
wherein ones of the pressing protrusions at the position corresponding to the second wiring portion are more densely distributed than ones of the pressing protrusions at the position corresponding to the first wiring portion.

18. The thin film deposition apparatus of claim 11, wherein the electrostatic chuck body comprises a cooler.

19. The thin film deposition apparatus of claim 11, further comprising a magnet for attracting the mask with a magnetic force.

20. The thin film deposition apparatus of claim 11, wherein a step difference portion is formed in an end portion of the cell, and
wherein the second wiring portion is positioned to correspond to the step difference portion in the mask.
